(19) United States
(12) Patent Application Publication
(10) Pub. No.: US 2025/0298387 A1
(43) Pub. Date: Sep. 25, 2025

(54) METHODS AND APPARATUS TO TRANSFORM A SCHEMATIC TO GENERATE AN ACTIONABLE OUTPUT

(71) Applicant: Vector Intelligence, LLC, Chicago, IL (US)

(72) Inventors: Nicholas Ryan Coffee, Gates, NY (US); Christian Signorelli, Lockport, IL (US)

(21) Appl. No.: 19/083,024

(22) Filed: Mar. 18, 2025

Related U.S. Application Data
(60) Provisional application No. 63/567,277, filed on Mar. 19, 2024.

(51) Int. Cl. G05B 19/042

(52) U.S. Cl. CPC G05B 19/0426; G05B 19/0428

(57) ABSTRACT

Systems, apparatus, articles of manufacture, and methods are disclosed to estimate and annotate schematics. As described herein, an apparatus including machine-readable instructions to identify a component of a schematic, wherein the identification of the component of the schematic is based on an analysis of the selected features of the schematic; generate a database including the identified component of the schematic; and generate an actionable output based on the identified component of the database, the actionable output including at least one of annotations to the schematic, a relational database, or a three-dimensional model.

### RELATED APPLICATION

This patent claims the benefit of U.S. Provisional Patent Application No. 63/567,277, which was filed on Mar. 19, 2024. U.S. Provisional Patent Application No. 63/567,277 is hereby incorporated herein by reference in its entirety. Priority to U.S. Provisional Patent Application No. 63/567,277 is hereby claimed.

### BRIEF DESCRIPTION OF THE DRAWINGS

FIG. 1 is a block diagram of an example architecture in which an example software program operates to transform a schematic to generate annotations to a schematic, a relational database, and a 3-D model.

FIG. 2 is a block diagram of an example implementation of the schematic transformation circuitry of FIG. 1.

FIG. 3 is a block diagram of an example implementation of a first database of FIG. 2.

FIG. 4 is a block diagram of an example implementation of a second database of FIG. 2.

FIG. 5A is a first example diagram of a display of the software program of FIG. 1.

FIG. 5B is a second example diagram of a display of the software program of FIG. 1.

FIG. 6 is a first flowchart representative of example machine readable instructions and/or example operations that may be executed, instantiated, and/or performed by example programmable circuitry to implement the schematic transformation circuitry of FIG. 2.

FIG. 7 is a second flowchart representative of example machine readable instructions and/or example operations that may be executed, instantiated, and/or performed by example programmable circuitry to implement the schematic transformation circuitry of FIG. 2.

FIG. 8 is a third flowchart representative of example machine readable instructions and/or example operations that may be executed, instantiated, and/or performed by example programmable circuitry to implement the schematic transformation circuitry of FIG. 2.

FIG. 9 is a fourth flowchart representative of example machine readable instructions and/or example operations that may be executed, instantiated, and/or performed by example programmable circuitry to implement the schematic transformation circuitry of FIG. 2.

FIG. 10 is a fifth flowchart representative of example machine readable instructions and/or example operations that may be executed, instantiated, and/or performed by example programmable circuitry to implement the schematic transformation circuitry of FIG. 2.

FIG. 11 is a block diagram of an example processing platform including programmable circuitry structured to execute, instantiate, and/or perform the example machine readable instructions and/or perform the example operations of FIGS. 6-10 to implement the schematic transformation circuitry of FIG. 2.

FIG. 12 is a block diagram of an example implementation of the programmable circuitry of FIG. 11.

FIG. 13 is a block diagram of another example implementation of the programmable circuitry of FIG. 11.

FIG. 14 is a block diagram of an example software/firmware/instructions distribution platform (e.g., one or more servers) to distribute software, instructions, and/or firmware (e.g., corresponding to the example machine readable instructions of FIGS. 6-10) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Schematics provide a plan for construction of a structure. As used herein, a schematic is defined to include blueprints, images, documents, and/or other renderings of architecture, construction, and/or other structures. The information obtained from the schematic includes components (e.g., beams, railing, glass, etc.) used, types of materials (e.g., steel, wood, concrete, etc.) of the components, quantities of the components and/or materials, various lengths and/or dimensions of the components, cost of the materials and/or components, and/or associated labor, etc., to complete the construction.

In the construction business, schematics are two-dimensional and viewed via a blueprint software. Annotation of a schematic is a time-consuming process wrought with the likelihood of error as a construction specialist must perform mental math to keep track of the structures and materials necessary to complete a given work task. Completion of annotation of a schematic can take the construction specialist hours and/or days. Additionally, the construction specialist must check their work to ensure that the process has been accurately performed.

Therefore, there exists a need in the construction business for a software program to process the schematic for the construction specialist and produce user-friendly actionable outputs from which the constructional specialist can proceed with their project. As disclosed herein, a schematic can be loaded by and/or otherwise input into a schematic processor to transform the schematic based on one or more selected features into transform the schematic into at least one of an annotated schematic, a relational database, and a 3D model to aid completion of the project of the schematic (e.g., to complete building of the structure depicted in the schematic).

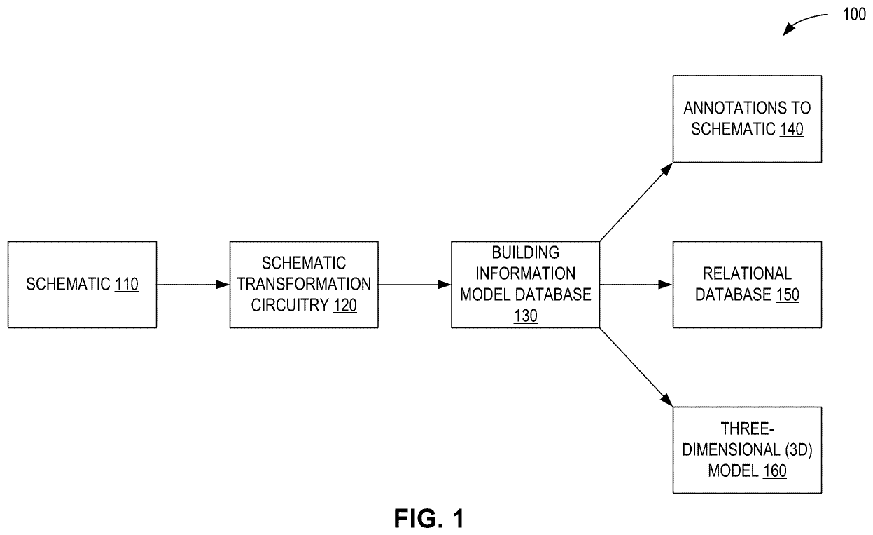

FIG. 1 is a block diagram of an example architecture 100 in which an example schematic 110 is input into example schematic transformation circuitry 120. Then, the schematic transformation circuitry 120 generates an example building information model database 130. The building information model database 130 includes information regarding building components from the schematic 110 to generate, via the schematic transformation circuitry 120, at least one of an example annotations to the schematic 140, an example relational database 150, and/or an example 3D model 160. In some examples, the schematic transformation circuitry 120 can generate one, two, or all of the annotations to schematic 140, the relational database 150, and/or the 3D model 160.

The building information model database 130 includes preliminary information regarding building components of the schematic 110. As used herein, a component is defined as a structure in the schematic (e.g., a beam, a board, a brick, a window, a door, a floor, etc.). Preliminary information of the schematic 110 can include identification of components included in the schematic 110, metadata included in the schematic 110, scale of the schematic 110, size of the components of the schematic 110, elevation of the components of the schematic 110, and other data identifiable from the schematic 110. In other words, the building information model database 130 includes a location of the component in three-dimensional space and a description of properties of the component of the schematic 110. The schematic transformation circuitry 120 generates from the building information model database 130 at least one of the annotations to the schematic 140, the relational database 150, and/or the 3D model 160 (e.g., the schematic transformation circuitry 120 generates an actionable output, etc.). The schematic transformation circuitry 120 generates from the building information model database 130 the actionable output based on geometric and statistical tests stored in the building information model database 130. The actionable output (e.g., the annotations to the schematic 140, the relational database 150, the 3D model 160, etc.) can be defined as an output from the schematic transformation circuitry 120 for user manipulation and/or user interaction.

Accordingly, the building information database 130 stores known components with known measurements to increase efficiency in identifying other components in other areas (e.g., other schematics, other areas in the same schematic, etc.). In some examples, by identifying text that represents a beam in a schematic, the building information database 130 can match other components that are used in a schematic when a beam is used as well.

The annotations to schematic 140 includes annotations corresponding to components of the schematic. In some examples, the annotations to the components of the schematic include attaching metadata to the component based on a component code associated with the component. In these examples, the schematic transformation circuitry 120 scans the schematic for component codes, extracts the component codes, and matches the component codes to metadata stored in a database. Then, the schematic transformation circuitry 120 labels the components of the schematic with corresponding metadata of the database. The metadata can include information regarding component dimensions, component weight, component orientation, and/or other features of the component. In some examples, the annotations to schematic 140 is a visual representation of the component. In some examples, the visual representation may include a color-coded component (e.g., red and/or green lines for beams and/or columns, respectively). Further, in some examples, the visual representation may include annotations corresponding to a dimension of the components.

In some examples, the schematic transformation circuitry 120 generates the relational database 150. The relational database 150 can define building areas in relation to each other. The relational database 150 includes at least one spreadsheet of the components included in the schematic. In some examples, the relational database 150 includes a list of all the components, the total weight of the components, the total linear footage of the components, measurements of the components, types of materials, grades of materials, specifications of paint for the components, and/or additional metadata. In some examples, the relational database 150 can store information regarding the spatial relationship between a first building area and a second building area. In this example, the first building area and the second building area are located within the same building, but do not fit within a single page of the schematic. Accordingly, the relational database 150 can store information regarding how the first building area relates in a three-dimensional spatial relationship to the second building area. However, in other examples, the relational database 150 can store information regarding the three-dimensional spatial relationships of more than two building areas and relate the building areas to each other across multiple pages.

In some examples, the schematic transformation circuitry 120 can generate the 3D model 160. The 3D model 160 can be used by the construction specialist to further detail the project and/or to present to a third party. In some examples, the schematic transformation circuitry 120 stores data including a coordinate and the dimension (e.g., weight, length, height, etc.) of the component (e.g., beam, column, etc.) for later generation into the 3D model 160.

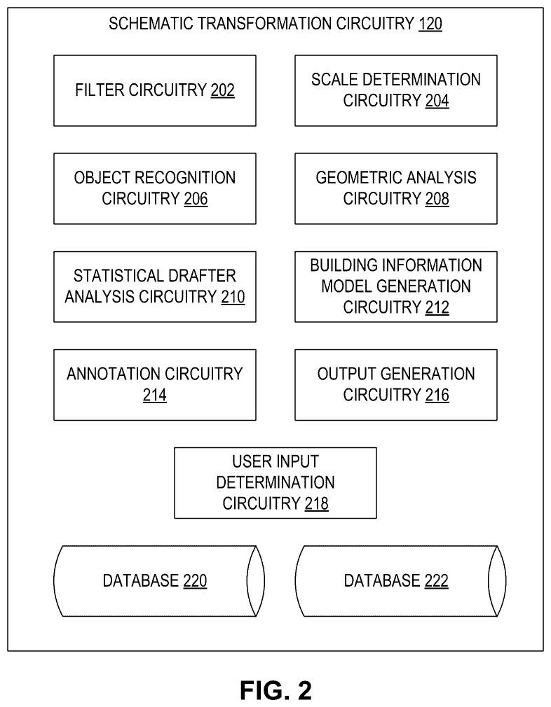

FIG. 2 is a block diagram of an example implementation of the schematic transformation circuitry 120 of FIG. 1 to process schematics to generate an actionable output. The schematic transformation circuitry of FIG. 2 includes example filter circuitry 202, example scale determination circuitry 204, example objection recognition circuitry 206, example geometric analysis circuitry 208, example statistical drafter analysis circuitry 210, example building information model generation circuitry 212, example annotation circuitry 214, example output generation circuitry 216, example user input determination circuitry 218, example database 220, and example database 222. The schematic transformation circuitry 120 of FIG. 2 may be instantiated (e.g., creating an instance of, bring into being for any length of time, materialize, implement, etc.) by programmable circuitry such as a Central Processor Unit (CPU) executing first instructions. Additionally or alternatively, the schematic transformation circuitry of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

The schematic transformation circuitry 120 is triggered to transform (e.g., process) a schematic (e.g., the schematic 110 of FIG. 1). In some examples, the receipt of the schematic triggers processing by the schematic transformation circuitry 120. In other examples, the trigger to process the schematic can be external (e.g., based on user input and/or other interface action to load a schematic stored in memory, etc.).

The filter circuitry 202 prepares the schematic for analysis. To prepare the schematic for analysis, the filter circuitry 202 filters the schematic to include a portion of the schematic containing the components for analysis. In some examples, the filter circuitry 202 determines a portion of the schematic based on an intent of the construction specialist. In these examples, the construction specialist can select via a user interface a category by which the filter circuitry 202 can filter the schematic. The category can include a type of the material of the component (e.g., steel, glass, plastic, etc.), the length of the component, the width of the component, a density of the component, and/or another physical characteristic of the component. In these examples, the filter circuitry 202 can filter the schematic to extract components of the schematic based on the selected category for further analysis. For example, the user can select via the user interface to filter the schematic to extract steel components. The filter circuitry 202, in this examples, can filter the schematic to output a schematic including only steel components of the original, non-filtered schematic.

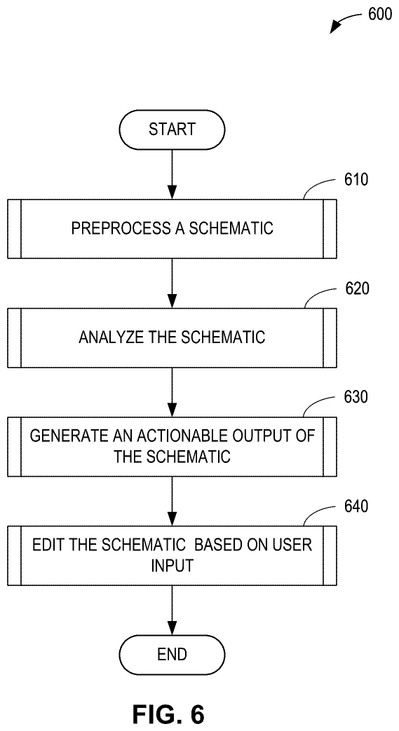

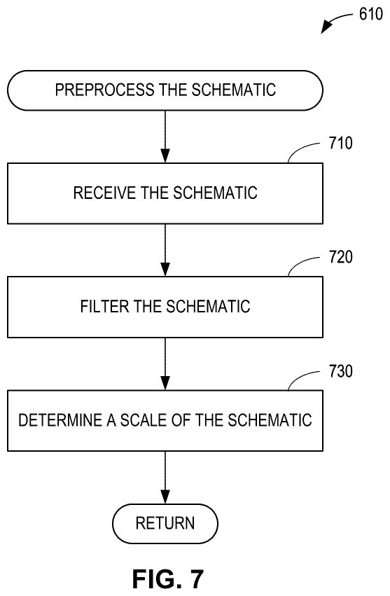

In some examples, the filter circuitry 202 filters the schematic by page title (e.g., filters out all pages that do not begin with the letter “S”, etc.). In other examples, the filter circuitry 202 scans the schematic and automatically selects the pages containing drawings of components for analysis. In still other examples, the filter circuitry 202 allows the user to manually select the pages for analysis. In some examples, the filter circuitry 202 may filter the schematic based on selection of pages and/or portions of a schematic, object recognition of components of the schematic (e.g., components in a portion of a building, a floor of a building, an entire building, etc.), and/or another similar filtration technique. Therefore, in examples where the schematic contains both text and a blueprint, the filter circuitry 202 can remove the text so that only the blueprint is analyzed by the schematic transformation circuitry 120. In these examples, the filter circuitry 202 can filter within the page of the schematic to include only relevant components and/or a portion of a page of the schematic. In some examples, the filter circuitry 202 is instantiated by programmable circuitry executing filter instructions and/or configured to perform operations such as those represented by the flowcharts of FIGS. 6 and 7 (blocks 610, and 710-720).

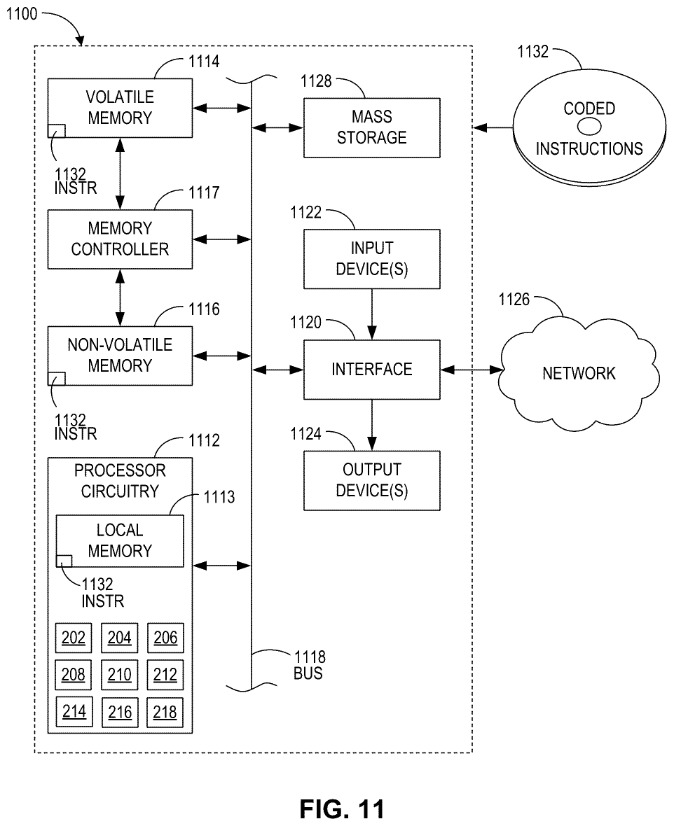

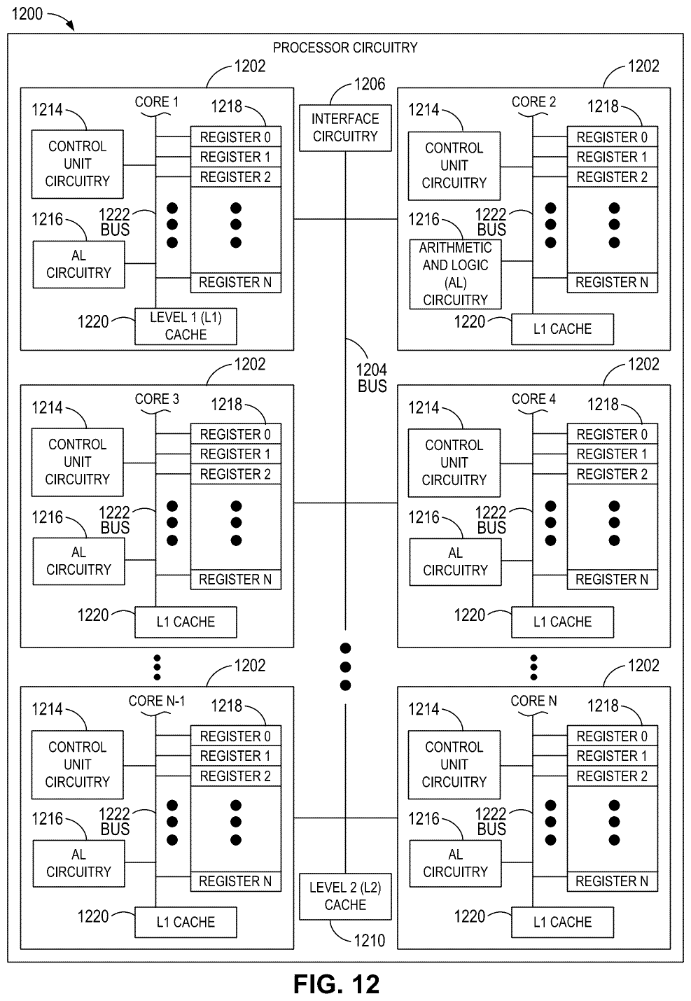

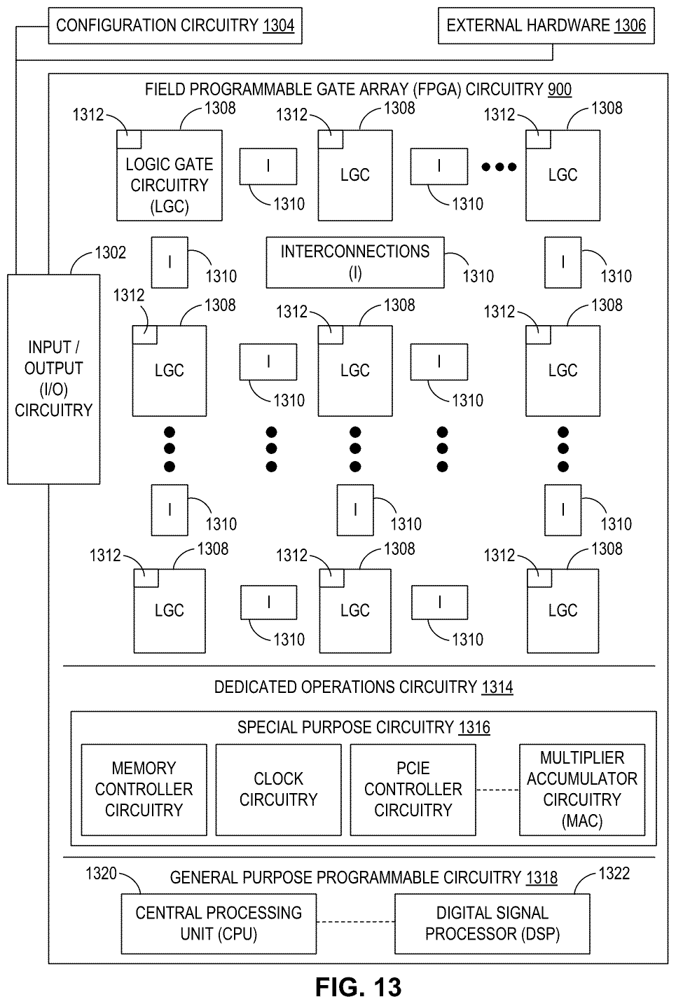

In some examples, the schematic transformation circuitry 120 includes means for filtering the schematic. For example, the means for filtering may be implemented by the filter circuitry 202. In some examples, the filter circuitry 202 may be instantiated by programmable circuitry such as the example programmable circuitry 1012 of FIG. 11. For instance, the filter circuitry 202 may be instantiated by the example microprocessor 1100 of FIG. 12 executing machine executable instructions such as those implemented by at least blocks 610 of FIG. 6 and 710-720 of FIG. 7. In some examples, the filter circuitry 202 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the filter circuitry 202 may be instantiated by any other combination of hardware, software, and/or firmware. For example, the filter circuitry 202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After the schematic is filtered by the filter circuitry 202, the scale determination circuitry 204 determines a drawing scale. The drawing scale of the schematic is a ratio corresponding to conversion of the component and/or building of the schematic to a life-size object (e.g., converting a building in a drawing of the schematic to a life-size building). An example drawing scale is that every ⅛ inch of a schematic corresponds to one foot in the three-dimensional world.

In some examples, the scale determination circuitry 204 scans the schematic for an indication of the scale. The indication of the scale can include a box where the drafter wrote the ratio, a symbol corresponding to the ratio, and/or any other indication of the scale. In other examples, the scale determination circuitry 204 polls the user to determine the scale the user wishes to apply to the schematic. Further, in still other examples, the scale determination circuitry 204 scans the schematic, and based on structural indications (e.g., sidewalk, height from ground level, approximations based on average heights, etc.) and/or geographic indications determines the scale of the schematic. Then, the scale determination circuitry 204 inputs to the schematic transformation circuitry 120 the determined drawing scale.

In some alternative examples, the scale determination circuitry 204 can determine a scale for the schematic based on a characteristic of a component labelled in the schematic. In these examples, the component is labelled as having a first dimension (e.g., a first length, a first width, etc.), and, when scaled to other components in the schematic, the first dimension corresponds to the scale of the schematic (e.g., a first component having the first dimension is compared to a second component having a fraction and/or a multiple of the first dimension of the first component, etc.). In some examples, the scale determination circuitry 204 is instantiated by programmable circuitry executing scale determination instructions and/or configured to perform operations such as those represented by the flowcharts of FIGS. 6 and 7 (blocks 610 and 730).

In some examples, the schematic transformation circuitry 120 includes means for determining the scale of the schematic. For example, the means for determining the scale may be implemented by the scale determination circuitry 204. In some examples, the scale determination circuitry 204 may be instantiated by programmable circuitry such as the example programmable circuitry 1012 of FIG. 11. For instance, the scale determination circuitry 204 may be instantiated by the example microprocessor 1100 of FIG. 12 executing machine executable instructions such as those implemented by at least blocks 610 of FIG. 6 and 730 of FIG. 7. In some examples, the scale determination circuitry 204 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the scale determination circuitry 204 may be instantiated by any other combination of hardware, software, and/or firmware. For example, the scale determination circuitry 204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After the scale determination circuitry 204 determines the

scale, the object recognition circuitry 206 selects features to analyze the schematic. After selection of a feature to analyze the schematic, the objection recognition circuitry 230 scans the schematic for the selected feature. The selected features determine the analysis of the schematic and resultant actionable output. Features to select for analysis of the schematic can include a component code, a thickness of a line of the components of the schematic, a length of the line of the components of the schematic, and/or other features of the components of the schematic (e.g., a type of the material of the component of the schematic, a weight of the component of the schematic, etc.). As used herein, a component code (e.g., a beam code) is a code embedded on components of a schematic that corresponds to information about the component (e.g., information stored in a database of the software program, etc.). In some examples, the component code corresponds to information concerning the type of material of the component, the dimensions of the component, the maker of the component, and/or other features of the component. In these examples, the component code is matched to a code in the database to access information about the component.

In some examples, the object recognition circuitry 206 selects to find all wide flange steel beam labels and extracts the beam codes (e.g., the component codes for wide flange steel beams). In these examples, the beam codes correspond to metadata stored in the database that can be used to label and/or annotate the beams.

In some examples, the object recognition circuitry 206 selects to identify components (e.g., beams) by thickness and/or length (e.g., by selected dimensions). In this example, components selected by thickness and/or length removes the possibility of the schematic transformation circuitry 120 annotating unrelated components. Therefore, in examples where components are selected based on thickness and length, the object recognition circuitry 206 scans the schematic for lines of a certain thickness (e.g., lines that are ⅛″ thick). After identification of lines of a predetermined thickness, the object recognition circuitry 206 extracts the component codes for these lines.

In still other examples, beams with a curve can be identified by the object recognition circuitry 206 as a series of straight lines with a curve and the beam codes attached to the series of straight lines.

After scanning the schematic for the selected features, the object recognition circuitry 206 attaches the identified features to the nearest component. Therefore, the object recognition circuitry 206 determines that a component is nearest to an identified feature and attaches that identified feature to the component (e.g., labels the component with the identified feature). Therefore, the object recognition circuitry 206 tags components with known sizes to inform further analysis of the component. In some examples, the nearest component is identified by the line of a component closest to the label (e.g., a first line of a first component is tagged with a component code if the first line is closer to the component code than a second line of a second component). In some examples, the nearest component is identified by whether the component is the nearest linear distance to the beam code as compared to other components.

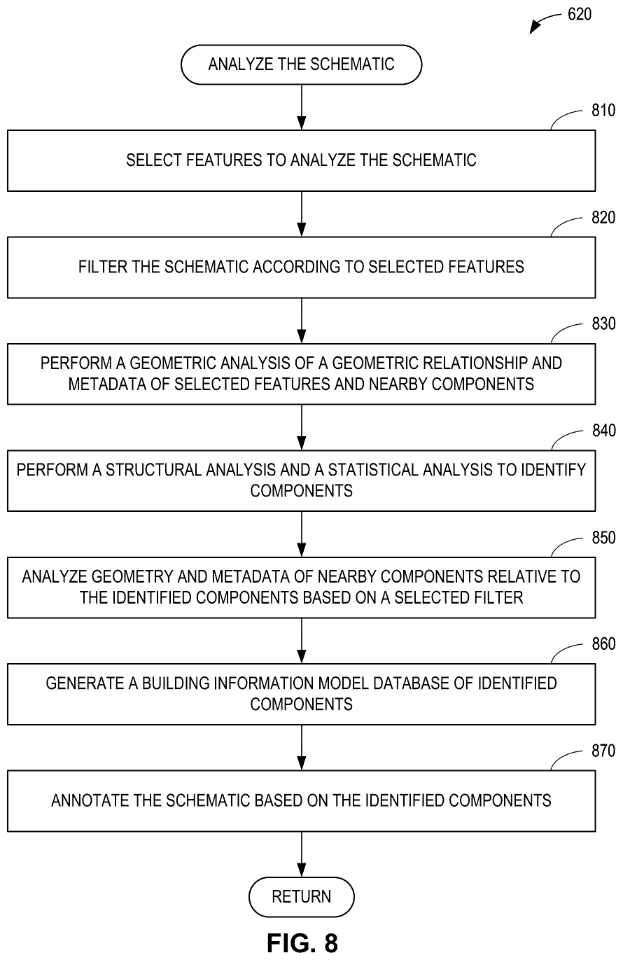

In other examples, the object recognition circuitry 206 selects to analyze the schematic using beam angle, and the object recognition circuitry 206 filters the schematic so that beams with the same angle are identified. Then, the object recognition circuitry 206 identifies the nearest component (e.g., beam or another structure of the schematic) based on the identified beam angle and labels the component with the beam angle. The object recognition circuitry 206 can repeat the process above to filter the schematic according to any selected feature so that components with varying features are identified and labeled for annotation. In some examples, the object recognition circuitry 206 is instantiated by programmable circuitry executing object recognition instructions and/or configured to perform operations such as those represented by the flowcharts of FIGS. 6 and 8 (blocks 620 and 810-820).

In some examples, the schematic transformation circuitry 120 includes means for selecting features to analyze the schematic. For example, the means for selecting features may be implemented by the object recognition circuitry 206. In some examples, the object recognition circuitry 206 may be instantiated by programmable circuitry such as the example programmable circuitry 1012 of FIG. 11. For instance, the object recognition circuitry 206 may be instantiated by the example microprocessor 1100 of FIG. 12 executing machine executable instructions such as those implemented by at least blocks 620 of FIG. 6 and 810-820 of FIG. 8. In some examples, the object recognition circuitry 206 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the object recognition circuitry 206 may be instantiated by any other combination of hardware, software, and/or firmware. For example, the object recognition circuitry 206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After selecting features to analyze in the schematic and analyzing the schematic based on the selected features by the object recognition circuitry 206, the geometric analysis circuitry 208 analyzes a geometric relationship and metadata of the selected features and nearby elements. The geometric relationship can be defined to include an angular relationship, a linear relationship, and/or a spatial arrangement of the components in the schematic relative to each other and/or relative to a common point. In some examples, the geometric analysis circuitry 208 determines an intent of a drafter of the schematic based on a geometric analysis of the selected features in comparison to schematic drafting norms (e.g., industry standards, accepted practices, etc.).

In some examples, the geometric analysis circuitry 208 performs a geometric analysis of the schematic after a statistical analysis of the schematic is performed with a filter selected based on the statistical analysis. In these examples, the filter filters out the identified components so the geometric analysis circuitry 208 can perform a geometric and spatial analysis of nearby components relative to the identified components. In other words, the geometric analysis circuitry 208 performs another geometric analysis to determine the spatial relationship between nearby components and identified components. In some examples, the filter selected after the statistical analysis filters according to line thickness. In these examples, the statistical drafter analysis circuitry 210 determines that in 90 of 100 cases a line that is both parallel and adjacent to a label has a thickness of 1.8 pt. Therefore, the geometric analysis circuitry 208 applies the filter to indicate beams with a thickness of 1.8 pt thickness and discard all others. Therefore, in these examples, the schematic transformation circuitry 120 can output lines that are the most likely, statistically and geometrically, to be a beam. In other examples, the geometric analysis circuitry 208 can determine whether a drafter has overdrawn a beam based on a sample of industry standards and identify the actual end of the beam. In some examples, the geometric analysis circuitry 208 is instantiated by programmable circuitry executing geometric analysis instructions and/or configured to perform operations such as those represented by the flowcharts of FIG. 8 (blocks 830 and 850).

In some examples, the schematic transformation circuitry 120 includes means for analyzing a geometric relationship. For example, the means for analyzing the geometric relationship may be implemented by the geometric analysis circuitry 208. In some examples, the geometric analysis circuitry 208 may be instantiated by programmable circuitry such as the example programmable circuitry 1012 of FIG. 11. For instance, the geometric analysis circuitry 208 may be instantiated by the example microprocessor 1100 of FIG. 12 executing machine executable instructions such as those implemented by at least blocks 830 and 850 of FIG. 8. In some examples, the geometric analysis circuitry 208 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the geometric analysis circuitry 208 may be instantiated by any other combination of hardware, software, and/or firmware. For example, the geometric analysis circuitry 208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After the geometric analysis circuitry 208 identifies an intent of the drafter based on the geometrical analysis, the statistical drafter analysis circuitry 210 performs a structural and a statistical analysis to identify a pattern in the drafter's intent to further identify building elements. In some examples, the statistical drafter analysis circuitry 210 identifies a composition of gridlines of a portion of the schematic. Then, the statistical drafter analysis circuitry 210 identifies the composition of the gridlines in another portion of the schematic to determine if the gridlines follow the same pattern as the previous portion. The statistical drafter analysis circuitry 210 compares the portions of the schematic to identify a pattern between the portions and determine drafter intent. After the statistical analysis is performed, a filter can be selected by the statistical drafter analysis circuitry 210 based on the determined pattern to be applied by the geometric analysis circuitry 208 to the schematic for refined analysis of drafter intent.

In some examples, the statistical analysis is performed to determine an average length and pattern of termination of gridlines. In these examples, the filter is selected to determine lines that fall within the range of the average length and pattern of the termination of the gridlines. Therefore, the geometrical analysis circuitry 208 can apply the filter selected by the statistical drafter analysis circuitry 210 so that lines that are terminated within a statistical range of an endpoint (e.g., within 30 pixels in the positive and negative direction of the endpoint, etc.) are retained in a schematic and others are filtered out. In some examples, the statistical analysis circuitry 210 can determine the filter to be applied by the geometric analysis circuitry 208 based on a dimension of a component (e.g., length, width, height, etc.), a material of a component, a gridline of a schematic, a property of drafting of the schematic (e.g., line thickness, line termination, etc.), and/or another identifiable property of the schematic and/or the drafter. In some examples, the statistical drafter analysis circuitry 210 is instantiated by programmable circuitry executing statistical drafter analysis instructions and/or configured to perform operations such as those represented by the flowcharts of FIG. 8 (block 840).

In some examples, the schematic transformation circuitry 120 includes means for performing a statistical analysis based on the drafter's intent. For example, the means for performing the statistical analysis may be implemented by the statistical drafter analysis circuitry 210. In some examples, the statistical drafter analysis circuitry 210 may be instantiated by programmable circuitry such as the example programmable circuitry 1012 of FIG. 11. For instance, the statistical drafter analysis circuitry 210 may be instantiated by the example microprocessor 1100 of FIG. 12 executing machine executable instructions such as those implemented by at least block 840 of FIG. 8. In some examples, the statistical drafter analysis circuitry 210 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the statistical drafter analysis circuitry 210 may be instantiated by any other combination of hardware, software, and/or firmware. For example, the statistical drafter analysis circuitry 210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After performance of statistical analysis by the statistical drafter analysis circuitry 210, the building information model generation circuitry 212 generates a building information model database (e.g., the building information model database 130 of FIG. 1). The building information model database includes preliminary information regarding building components of the schematic. In some examples, the building information model database includes information collected by the scale determination circuitry 204 and/or the objection recognition circuitry 206 of the components of the schematic. The preliminary information of the schematic can include identification of components in the schematic, metadata included in the schematic, scale of the schematic, and other data identifiable from the schematic. In some examples, the building information model generation circuitry 212 is instantiated by programmable circuitry executing building information model generation instructions and/or configured to perform operations such as those represented by the flowchart of FIG. 8 (block 860).

In some examples, the schematic transformation circuitry 120 includes means for generating a building information model database. For example, the means for generation the building information model database may be implemented by the building information model generation circuitry 212. In some examples, the building information model generation circuitry 212 may be instantiated by programmable circuitry such as the example programmable circuitry 1012 of FIG. 11. For instance, the building information model generation circuitry 212 may be instantiated by the example microprocessor 1100 of FIG. 12 executing machine executable instructions such as those implemented by at least block 860 of FIG. 8. In some examples, the building information model generation circuitry 212 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the building information model generation circuitry 212 may be instantiated by any other combination of hardware, software, and/or firmware. For example, the building information model generation circuitry 212 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After generation of the database of identified building elements by the building information model generation circuitry 212, the annotation circuitry 214, in some examples, measures the nearest component. In some examples, the annotation circuitry 214 measures the component by extending a line by a predefined amount to define the length (e.g., full beam length, etc.) of the component. The annotation circuitry 214 determines the predefined amount by finding the x-y coordinates of the ends of the component and calculating the slope between the ends of the component. The annotation circuitry 214 uses the drawing scale to determine the predefined amount based on the calculated slope and distance between the ends of the component. However, the annotation circuitry 214 can measure the component by any means of calculation (e.g., endpoint selection, etc.).

Additionally or alternatively, the annotation circuitry 214 annotates the labelled components. In some examples, annotation by the annotation circuitry 214 includes the dimensions (length, width, height) of the component, the material of the component (e.g., steel, glass, metal, etc.), the orientation of the component (e.g., beam angle, etc.), and/or any other annotation of the schematic. In some examples, the annotation circuitry 214 matches the label of the component corresponding to a component code to a code value of metadata stored in a database 220. In some examples, the code value can correspond to a desired feature for output of the annotation (e.g., material cost, material quantity, material type, and/or other features).

In some examples, the annotation circuitry 214 labels the components according to a component label measurement process. The component label measurement process identifies the closest component (e.g., beam or another component of the schematic) to the identified feature by connecting both ends of the component to the respective ends of a label for the identified feature. Then, the annotation circuitry 214 generates a numerical value which signifies the distance between the label and the component. The smallest distance between the label and the component corresponds to a match as the correct label for that component. For example, a first component connects a first line and a second line to respective ends of a label with respective first and second values, and a second component connects a third line and a fourth line to the respective ends of the label with respective third and fourth values. Because the first and second values are lower, the label matches the first component. After the component is labelled, the annotation circuitry 214 removes the component from the total set of components, preventing labelling to be completed twice for the same component.

In some examples, the annotation circuitry 214 annotates outer edge beams of the schematic that connect into the concrete. In these examples, the annotation circuitry 214 identifies beams that do not connect to another beam and follows the extension of the beam until another line runs perpendicular to the extension of the beam. The annotation circuitry 214 annotates the perpendicular line. In some examples, the perpendicular line is concrete. Therefore, the annotation circuitry 214 can identify extension of vertical beams into concrete. In some examples, the annotation circuitry 214 is instantiated by programmable circuitry executing annotation instructions and/or configured to perform operations such as those represented by the flowcharts of FIG. 8 (block 870).

In some examples, the schematic transformation circuitry 120 includes means for annotating features of the schematic. For example, the means for annotating may be implemented by the annotation circuitry 214. In some examples, the annotation circuitry 214 may be instantiated by programmable circuitry such as the example programmable circuitry 1012 of FIG. 11. For instance, the annotation circuitry 214 may be instantiated by the example microprocessor 1100 of FIG. 12 executing machine executable instructions such as those implemented by at least block 870 of FIG. 8. In some examples, the annotation circuitry 214 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the annotation circuitry 214 may be instantiated by any other combination of hardware, software, and/or firmware. For example, the annotation circuitry 214 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

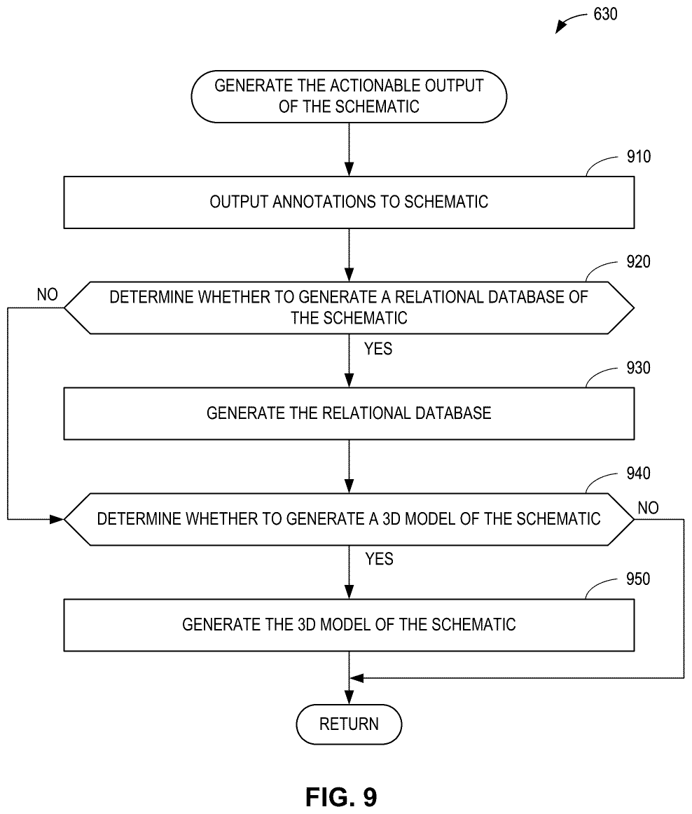

After annotation by the annotation circuitry 214, the output generation circuitry 216 outputs the actionable output of the schematic. In some examples, the actionable output includes an updated schematic incorporating annotations generated by the output generation circuitry 216. In other examples, the output generation circuitry 216 outputs the relational database and/or the 3D model. Further, in some examples, the actionable output includes at least one of the annotations to the schematic, the relational database, and/or the 3D model. After output of the actionable output by the output generation circuitry 216, the user can download the file for use outside the software program and/or can edit the actionable output. In other examples, the output generation circuitry 216 can output the actionable output to be saved to a user profile and/or for download for use in another system (e.g., another schematic viewing software, schematic editing software, component ordering software, and/or another third party software, etc.). In some examples, the output generation circuitry 216 is instantiated by programmable circuitry executing output generation instructions and/or configured to perform operations such as those represented by the flowcharts of FIG. 9 (blocks 910-950).

In some examples, the schematic transformation circuitry 120 includes means for generating the actionable output of the schematic. For example, the means for generating the actionable output of the schematic may be implemented by the output generation circuitry 216. In some examples, the output generation circuitry 216 may be instantiated by programmable circuitry such as the example programmable circuitry 1012 of FIG. 11. For instance, the output generation circuitry 216 may be instantiated by the example microprocessor 1100 of FIG. 12 executing machine executable instructions such as those implemented by at least blocks 910-950 of FIG. 9. In some examples, the output generation circuitry 216 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the output generation circuitry 216 may be instantiated by any other combination of hardware, software, and/or firmware. For example, the output generation circuitry 216 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

After generation of the actionable output by the output generation circuitry 216, the user input determination circuity 218 determines changes desired by the user to the actionable output of the building information model generation database. In some examples, a user can select, via a user interface, the actionable output for the schematic via the user input determination circuitry 218. In these examples, the user input determination circuitry 218 can generate the annotations to the schematic, the relational database of the schematic, and/or the 3D model of the schematic.

In some examples, the user input determination circuitry 218 can configure the schematic to track and/or calculate new metadata based on adjustments made to the schematic so that the schematic is seamlessly integrated with other programs (e.g., the user input determination circuitry 218 configures the schematic to include a Measure-Object operation and/or any other operation to track metadata). In these examples, the schematic can be edited in another software and reuploaded. The reuploaded schematic contains the edits made outside the software program and the annotations made by the schematic transformation circuitry 120. Further, in these examples, the reuploaded, annotated schematic can be used in generation of the relational database and/or the 3D model.

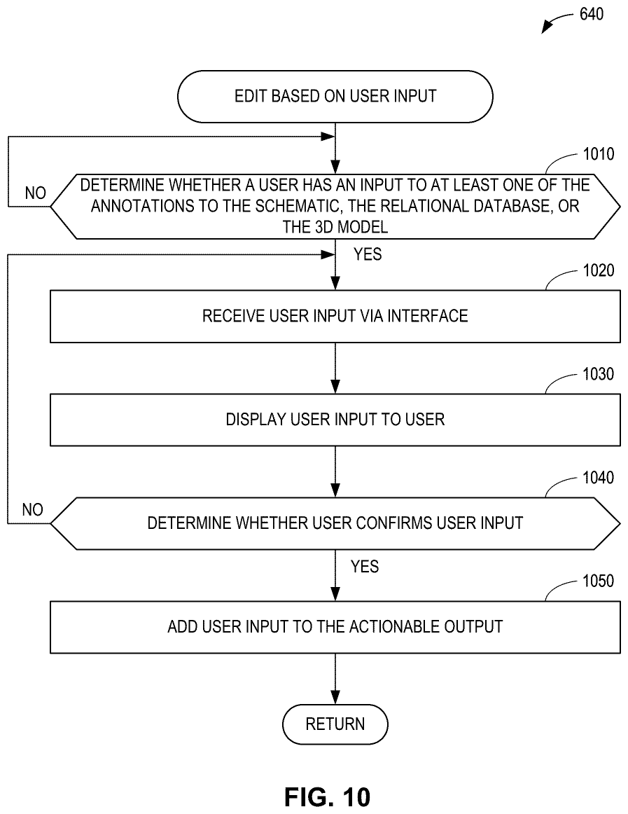

In some examples, the user input determination circuitry 218 determines edits based on user input. In these examples, the user input determination circuitry 218 determines whether the user has input, via a user interface or other input device, a modification to at least one of the annotations to the schematic, the relational database, or the 3D model. For example, the user input determination circuitry 218 detects that a user has input a change to at least one of the schematic, the relational database, and/or the 3D model to add a component (e.g., a beam, a door, a window, etc.). The user input determination circuitry 218 can receive the user input and display the user input to the user for confirmation of the modification. In the above example, the user input determination circuitry 218 displays the above added components to the user (e.g., the beam, the door, the window, etc.) for the user to confirm the addition. After confirmation of the user input by the user, the user input determination circuitry 218 can integrate the user input with the edited output (e.g., the at least one of the annotations to the schematic, the relational database, or the 3D model). In some examples, the user input determination circuitry 218 is instantiated by programmable circuitry executing user input determination instructions and/or configured to perform operations such as those represented by the flowcharts of FIGS. 6 and 10 (blocks 640, 1010-1050).

In some examples, the schematic transformation circuitry includes means for editing based on user input. For example, the means for editing may be implemented by the user input determination circuitry 218. In some examples, the user input determination circuitry 218 may be instantiated by programmable circuitry such as the example programmable circuitry 1012 of FIG. 11. For instance, the user input determination circuitry 218 may be instantiated by the example microprocessor 1100 of FIG. 12 executing machine executable instructions such as those implemented by at least blocks 640 of FIG. 6, and 1010-1050 of FIG. 10. In some examples, the user input determination circuitry 218 may be instantiated by hardware logic circuitry, which may be implemented by an ASIC, XPU, or the FPGA circuitry 1200 of FIG. 13 configured and/or structured to perform operations corresponding to the machine readable instructions. Additionally or alternatively, the user input determination circuitry 218 may be instantiated by any other combination of hardware, software, and/or firmware. For example, the user input determination circuitry 218 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

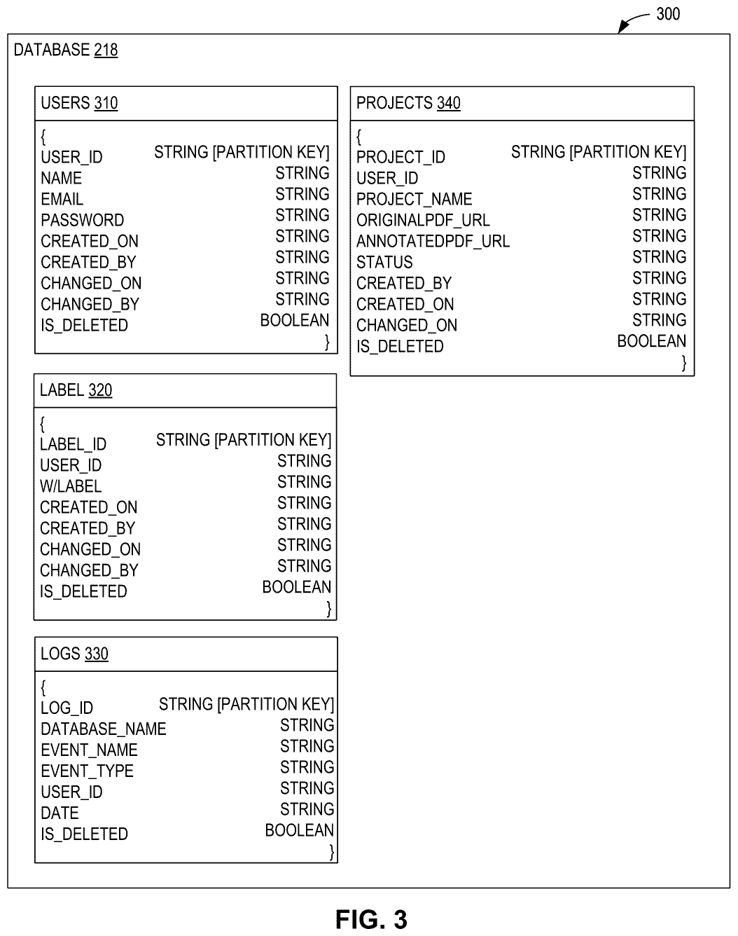

The database 220 stores data corresponding to recovery of the software program. In instances of failure and/or reboot, the database 220 restores the data corresponding to instantiation of the software program. Further, the database 220 stores tables with relationships between entities like users, projects, labels, and documents to enable tracking across projects. The database 220, due to the relationships established between tables, secures user handling, coordinates annotate and store cycles, and organizes projects. Therefore, the component codes extracted by the object recognition circuitry 206 and utilized for annotation by the annotation circuitry 214 are stored in the database 220. The annotation circuitry 214 matches the component codes to codes corresponding to metadata in the database 220. Then, the annotation circuitry 214 uses the metadata to annotate the component nearest to the component code. In some examples, the database 220 can be instantiated by an Amazon DynamoDB®. In other examples, the database 220 can be instantiated by a database employing elastic block storage for data backup and recovery (e.g., Amazon Elastic Container Service®). The database 220 is further detailed in connection with FIG. 3.

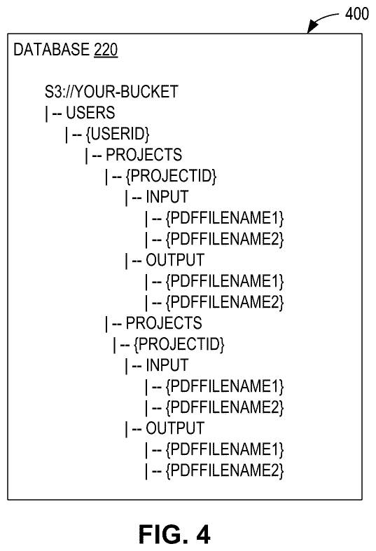

The database 222 stores files containing schematics, blueprints, user profile information, coding files, updates, and/or any file-based information. The database 222 coordinates the storage of a schematic profile so that the schematic profile may be accessed at a later date. Further, the database 222 allows storage of an annotated schematic, a 3D model, a relational database, and any other generated documents to the profile for the schematic. The database 222 can be instantiated as an Amazon Simple Storage Service® (Amazon S3®). The database 222 is further detailed in connection with FIG. 4.

While an example manner of implementing the schematic transformation circuitry 120 of FIG. 1 is illustrated in FIG. 2, one or more of the elements, processes, and/or devices illustrated in FIG. 2 may be combined, divided, re-arranged, omitted, eliminated, and/or implemented in any other way. Further, the filter circuitry 202, the scale determination circuitry 204, the object recognition circuitry 206, the geometric analysis circuitry 208, the statistical drafter analysis circuitry 210, the building information model generation circuitry 212, the annotation circuitry 214, the output generation circuitry 216, the user input determination circuitry 218, the database 220, the database 222, and/or, more generally, the example schematic transformation circuitry 120 of FIG. 2, may be implemented by hardware alone or by hardware in combination with software and/or firmware. Thus, for example, any of the filter circuitry 202, the scale determination circuitry 204, the object recognition circuitry 206, the geometric analysis circuitry 208, the statistical drafter analysis circuitry 210, the building information model generation circuitry 212, the annotation circuitry 214, the output generation circuitry 216, the user input determination circuitry 218, the database 220, the database 222,, and/or, more generally, the example schematic transformation circuitry 120, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example schematic transformation circuitry 120 of FIG. 2 may include one or more elements, processes, and/or devices in addition to, or instead of, those illustrated in FIG. 2, and/or may include more than one of any or all of the illustrated elements, processes and devices.

FIG. 3 is a diagram representative of the database 220. In the illustrated example of FIG. 3, the environment 300 of the database 220 includes a users table 310, a label table 320, a logs table 330, and a projects table 340. The listed tables facilitate efficient data retrieval. For example, in the projects table 340, the partition key is project_id. The attributes in each table store relevant data (e.g., user information (log-in, password, history, etc.), project information, labels, document details, and logs). The environment 300 is designed to support various functionalities of the software program, including user management, project tracking, label management, document annotation, and activity logging. Relationships between items in different tables can be facilitated and managed using consistent attribute values.

Further, new users and user credentials are stored in the database 220. User credentials entered via the frontend are sent to the database 220 for user identity actions like login, registration, and password resets. User registration allows new users to securely create an account by entering their name, email address, and password, which is stored in the database 220 for future authentication. Existing users with credentials already stored can navigate to a login screen from registration and enter their email and password to access the estimation software.

FIG. 4 is a diagram representative of the database 222. In this example, the database 222 is organized as an S3® bucket schema. In this example, the environment 400 of the database 222 is organized by users. Therefore, when a user identification (hereinafter, “user id”) is entered into the software, the bucket corresponding to that user is pulled. Then, underneath the user id, the next bucket is a projects folder where within each projects folder is an input and output folder. The structure of the database 222 allows for access in two ways: (1) by user id to access all projects for that user, and (2) by project id within a specific user id. The advantages of this structure are that projects can be accessed by user id, allows per project access with the added projects folder, and input and output files remain separate.

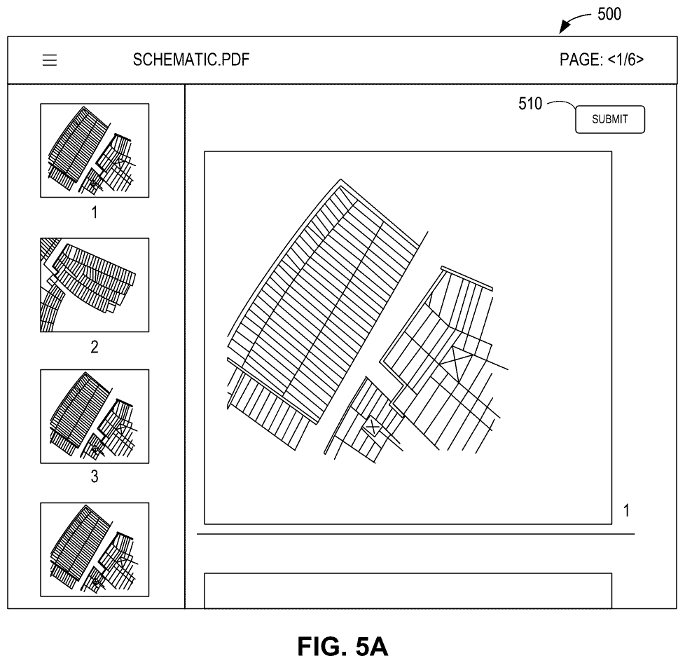

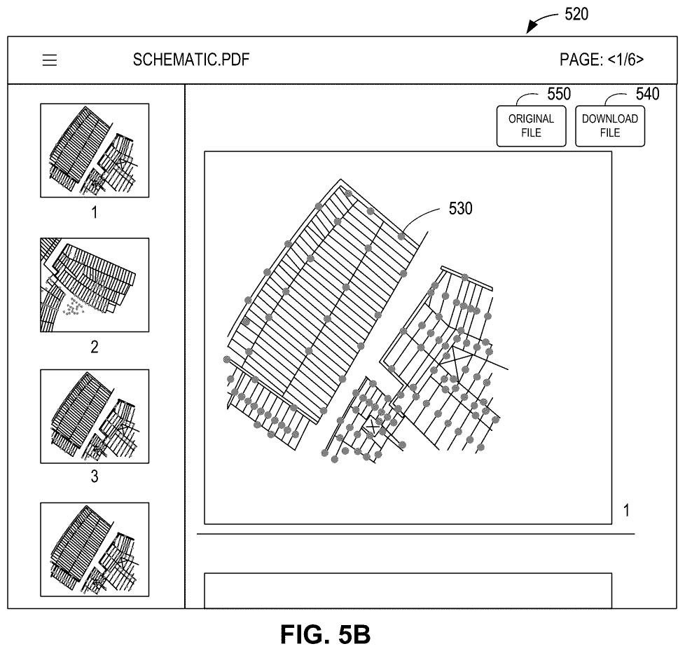

After user authentication by the database 220, the database 222 can be accessed by the user. In some examples, after login, the user navigates to a landing page where their user id provides quick access options to view existing projects or create new projects. If a user chooses to view previously transformed schematics (e.g., projects), then the corresponding bucket of the database 222 is accessed to view a list of the user's past projects with a project name and a last modified date. Users can search and sort projects to locate a specific project. Further, a user can select to start a new project and upload a schematic from a device (as shown in the example of FIG. 5A). The unannotated schematics are stored in the database 222, and the schematic transformation circuitry 120 outputs the actionable output (e.g., the annotations to the schematic, the 3D model, the relational database, etc.) for storage in the database 222.

FIG. 5A is an example display 500 of an unannotated schematic. The unannotated schematic is displayed to show the pages of the unannotated schematic. Further, the user can, via the filter circuitry 202, manually select pages for annotation and/or filtering. Users can append additional pages requiring annotations to the schematic. Additionally, buttons, like button 510, allow the user to select when the schematic transformation circuitry 120 initiates generation of the actionable output.

FIG. 5B is an example display 520 of an annotated schematic. In this example, the annotations are represented as circular grey markings, such as the marking 530, on the schematic. FIG. 5B is one example representation of an annotation by the annotation circuitry 214 of the schematic transformation circuitry 200. In some examples, the user can hover a cursor over the marking 530 to display the metadata associated with that component. In some examples, the component is a beam, and the user may hover over the marking 530 to display beam length, beam thickness, material, and/or other identifying information stored in metadata for that beam. In some examples, the metadata used to annotate the schematic is displayed with the display 520 in a separate column. In these examples, the metadata displayed corresponds to the data for the components displayed in the display 520. In some examples, the metadata displayed can include the linear footage and/or weight of the components display in the display 520. In some examples, the display 520 of FIG. 5B will include a summary list to click and filter components of a specific size.

The unannotated schematic of FIG. 5A and the annotated schematic of FIG. 5B are stored in the database 222 for future reference on a per project and/or per user basis. The display 520 allows for download of a relational database via the download file button 540. In these examples, the button 540 triggers a relational database to be generated for the annotated schematic. In some examples, the relational database includes at least one spreadsheet. The relational database can include a list of all the materials to complete the schematic including information such as the total weight of the materials and/or the total linear footage. In some examples, the display 520 will include a button to enable download of the annotations to the schematic and/or the button 540 can, additionally or alternatively, enable download of the annotations to the schematic. Further, the display 520 allows for reversion and/or display of the original file (e.g., the unannotated schematic of FIG. 5A) via the original file button 550. Therefore, the display may toggle between the unannotated schematic display 500 and the annotated schematic display 520 through use of the button 550.

Flowcharts representative of example machine readable instructions, which may be executed by programmable circuitry to implement and/or instantiate the schematic transformation circuitry of FIG. 2 and/or representative of example operations which may be performed by programmable circuitry to implement and/or instantiate the schematic transformation circuitry of FIG. 2, are shown in FIGS. 6-10. The machine readable instructions may be one or more executable programs or portion(s) of one or more executable programs for execution by programmable circuitry such as the programmable circuitry 1112 shown in the example processor platform 1100 discussed below in connection with FIG. 11 and/or may be one or more function(s) or portion(s) of functions to be performed by the example programmable circuitry (e.g., an FPGA) discussed below in connection with FIGS. 11 and/or 12. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 6-10, many other methods of implementing the example schematic transformation circuitry may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 6-10 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 6 is a flowchart representative of example machine readable instructions and/or example operations 600 that may be executed, instantiated, and/or performed by programmable circuitry to transform a schematic. The example machine-readable instructions and/or the example operations 600 of FIG. 6 begin at block 610, at which the filter circuitry 202 and the scale determination circuitry 204 preprocess a schematic. In some examples, the filter circuitry 202 receives the schematic and filters the schematic. The portion of the schematic remaining after filtering by the filter circuitry 202 is the portion to be analyzed. In some examples, the filter circuitry 202 filters according to user selection, via a user interface or other user input device (e.g., user selection of a material type, material length, material characteristic, etc.); document title; and/or component recognition. The scale determination circuitry 204 determines the drawing scale used in the portion of the schematic to be analyzed via user input and/or component recognition. After determination of the scale by the scale determination circuitry 204, control proceeds to block 620.

Then, at block 620, the object recognition circuitry 206, the geometric analysis circuitry 208, the statistical drafter analysis circuitry 210, the building information model generation circuitry 212, the annotation circuity 214, and the output generation circuitry 216 analyze the schematic. The object recognition circuitry 206 selects features to use for analysis of the document. In some examples, the object recognition circuitry 206 scans the schematic for components. The object recognition circuitry 206 can scan the schematic using an object recognition technique (e.g., based on line thickness, length, etc.). The object recognition circuitry 206 can extract component codes of identified components to be matched with metadata in the database 220.

Then, the object recognition circuitry 206 analyzes the document according to the extracted component codes and measures the distance between a component code to nearby components. The component nearest to the component code (e.g., the nearest component) is matched with that component by the object recognition circuitry 206 to ensure accurate measurement and annotation by the annotation circuitry 214.

The geometric analysis circuitry 208 performs a geometric analysis of the features selected by the object recognition circuitry 206 to determine a geometric relationship and/or a spatial arrangement of components in the schematic relative to each other and/or relative to a common point. For example, the geometric analysis circuitry 208 identifies the location and orientation of a first component and compares it to the location and orientation of a second component to determine a geometric relationship (e.g., angular relationship, orientation, etc.) and/or a spatial arrangement (e.g., distance, dimensions, etc.) between the first and second components. Based on the geometric analysis, the geometric analysis circuitry 208 determines an intent of the drafter based on schematic drafting norms, which can inform error and/or areas of deviation in the schematic. In some examples, the geometric analysis circuitry 208 determines from the drawing of at least one component of the schematic (e.g., the drawings of at least one beam, etc.) in comparison to an industry standard of the component whether the user intended to draw the component that is depicted in the industry standard.

The statistical drafter analysis circuitry 210 performs a structural and a statistical analysis to identify a pattern in the drafter's intent to identify building elements. In other words, the statistical drafter analysis circuitry 210 analyzes drafter intent based on the schematic itself to further identify building components. The statistical drafter analysis circuitry 210 compares the schematic to averages and/or performs statistical tests to determine whether the drafter intended to draw a building component. As discussed above, the statistical analysis can determine whether a drafter terminated a component at a certain position on the schematic and/or whether a component is located at a given location. Accordingly, the statistical drafter analysis circuitry 210 can select a filter (e.g., line thickness, line length, etc.) for the geometric analysis circuitry 208 to apply to the schematic in another analysis to identify components with greater accuracy.

The building information model generation circuitry 212 generates a database of components identified based on the analyses performed by the object recognition circuitry 206, the geometric analysis circuitry 208, and the statistical drafter analysis circuitry 210. The identified components can include an identification of components in the schematic, metadata related to the components in the schematic, scale of the schematic, size of components in the schematic, elevation of the components in the schematic, and other data identifiable from the schematic based on the analyses performed.

Then, the annotation circuitry 214 annotates the identified components. The annotation circuitry 214 can annotate the schematic with data stored for the identified component. In some examples, the annotation circuitry 214 annotates the identified components with the metadata corresponding to a component code for the identified component from the database 220. After analysis of the schematic, control proceeds to block 630.

At block 630, the output generation circuitry 216 generates an actionable output for the schematic. The actionable output includes at least one of the annotations to the schematic, the relational database for the schematic, and/or the 3D model of the schematic. The actionable output for the schematic may be stored in the database 222. In some examples, after and/or in response to annotation by the annotation circuitry 214, the output generation circuitry 216 outputs the annotations to the schematic. In these examples, the output generation circuitry 216 then determines whether to output a relational database and/or a 3D model for the schematic. In some examples, the determination of whether to output the relational database and/or the 3D model is based on input (e.g., via the button 540) or default settings. After generation of the actionable output for the schematic by the output generation circuitry 216, the process ends.

FIG. 7 is a flowchart representative of example machine readable instructions and/or example operations 610 that may be executed, instantiated, and/or performed by programmable circuitry to prepare the schematic. The example machine-readable instructions and/or the example operations 610 of FIG. 7 begin at block 710, at which the filter circuitry 202 receives the schematic. The unannotated schematic is stored in the database 222 after receipt. The unannotated schematic is stored in the database 222 under a folder generated for the schematic (e.g., a portion of the database 222 reserved for the project).

After receipt of the schematic, the filter circuitry 202 filters the schematic at block 720. The filter circuitry 202 can filter the schematic by determining via user input a category by which to filter the schematic. The category can include a type of material of the component and/or a physical characteristic of the component. In other examples, the filtering of the schematic by the filter circuitry 202 can be based on the numbering of the pages, the naming of the pages, manual selection by the user of pages for annotation, scanning and selection of pages for annotation by the filter circuitry 202, and/or any other method of filtering. Additionally or alternatively, the user can append additional pages to the input schematic. These additional pages can be filtered by the filter circuitry 202. The filter circuitry 202 can filter the schematic by page or by sections of pages to determine a portion of the schematic to be used for analysis. For example, the filter circuitry 202 may filter a page containing both text and a blueprint so that only the blueprint is analyzed by the schematic transformation circuitry 120. After filtering of the schematic by the filter circuitry 202, control proceeds to block 730.

At block 730, the scale determination circuitry 204 determines the scale of the schematic. In some examples, the scale determination circuitry 204 determines the scale of the schematic by scanning the schematic for indications of scale (as described above in connection to FIG. 2). However, in other examples, the user inputs the scale of the schematic. Additionally or alternatively, the scale determination circuitry 204 estimates the drawing scale based on the proportions of the schematic with other geographic and/or architectural features. In these examples, a component can be labelled as having a first length, and when scaled to other components in the schematic, a scale of the schematic can be estimated. For example, a beam can be labelled as having a length of three feet, and, when compared to a door in the schematic, the door can be estimated as 6 feet tall because the beam is half the height of the door. After the scale determination circuitry 204 determines the scale of the schematic, control returns to block 610 of FIG. 6.

FIG. 8 is a flowchart representative of example machine readable instructions and/or example operations 620 that may be executed, instantiated, and/or performed by programmable circuitry to analyze the schematic. The example machine-readable instructions and/or the example operations 620 of FIG. 8 begin at block 810, at which the object recognition circuitry 206 selects features to analyze in the schematic. The selected feature is analyzed further and annotated by the annotation circuitry 214. Therefore, the selection of a feature by the object recognition circuitry 206 provides a baseline for the generation of the actionable output. As detailed above in connection with FIG. 2, the selected features can include a component code, a thickness of a line of the components of the schematic, the length of a line of the components of the schematic, and/or other features of the components of the schematic. The object recognition circuitry 206 can poll the user for selection of features and/or apply a selection of default features.

In some examples, the object recognition circuitry 206 scans the schematic for component codes. The component codes are used to identify features of the component to which they are nearest (e.g., the component codes identify features to which they are the nearest in proximity and/or linear distance). Additionally or alternatively, the object recognition circuitry 206 can scan the schematic for categories of features for selection (e.g., selects all objects with wide flange steel beam labels, objects with a certain thickness and/or length, etc.).

As an example, the object recognition circuitry 206 can select that lines that are ⅛″ thick are the selected feature. In this example, subsequent analysis of the schematic is based on lines that are ⅛′ thick. In some examples, lines that are ⅛″ thick are selected because that corresponds to components that are beams or other identified components. After selection of features by the object recognition circuitry 206, control proceeds to block 820.

At block 820, the object recognition circuitry 206 filters according to the selected features. The object recognition circuitry 206 filters the schematic to identify features of the schematic corresponding to the selected features.

In accordance with the above example, if the selected feature is lines that are ⅛″ thick, then the objection recognition circuitry 230 will filter the schematic to identify lines that are ⅛″ thick. In other examples, the selected feature can be a certain beam angle (e.g., orientation). Therefore, the object recognition circuitry 206 filters the schematic to identify all instances where a component (e.g., a beam) is at the certain beam angle. However, other features (e.g., material identity, length, width, height, etc.) can be used to filter the schematic for a given feature. In some examples, the object recognition circuitry 206 can filter according to one selected feature. However, in other examples, the object recognition circuitry 206 can filter according to two or more selected features. Therefore, feature selection and filtration can occur on an iterative basis based on the features for annotation. After identification of the components of the schematic corresponding to the selected feature(s), control proceeds to block 830.

At block 830, the geometric analysis circuitry 208 performs a geometric analysis of a geometric relationship and metadata of selected features and nearby components. The geometric analysis circuitry 208 performs the geometric analysis to determine the spatial relationship (e.g., positional relationship) between the selected features and the nearby components.

Further, the geometric analysis circuitry 208 determines whether a drafter strayed from their likely intent (e.g., committed an error) while drafting the schematic as compared to industry norms (e.g., a reference), and corrects the error to comply with industry norms. As used herein, a reference can be defined as a standard and/or a measurement that describe a standard system of dimensions (e.g., length, width, height, etc.) for schematic components. For example, when ending a drawing of a component, a drafter can end a drawing of a component a first number of pixels before the actual end of the component and/or can overdraw a second number of pixels over the actual end of the component. If a drafter overdraws or under draws a predicted end of the component, the geometric analysis circuitry 208, based on industry norms, recognizes the error and identifies the actual end of the component. Based on the identification of the actual end of the component, the geometric analysis circuitry 208 can generate an updated schematic to reflect the actual end of the component (e.g., extend and/or retract the component length to the actual end of the component, etc.). In some examples, the geometric analysis circuitry 208 can generate the updated schematic to correct an error to a component identified after analysis of the schematic and generation of the actionable output (e.g., the annotations to the schematic, the relational database, the 3-D model, etc.). In other examples, the geometric analysis circuitry 208 can generate the updated schematic to correct an identified component during analysis by the schematic transformation circuitry 120 (e.g., in real time, etc.).

At block 840, the statistical drafter analysis circuitry 210

performs a structural analysis and a statistical analysis to identify components of the schematic. The statistical drafter analysis circuitry 210 performs a structural analysis by determining the structural composition of the schematic (e.g., placement of gridlines, components, etc.). Further, the statistical drafter analysis circuitry 210 performs a statistical analysis by identifying a pattern based on the structural composition of the schematic. The statistical drafter analysis circuitry 210 can determine based on averages and/or statistical tests of drafters and/or schematics the components of the schematic and the expected dimensions of the components of the schematic (e.g., the length of a component, thickness of a component, etc.). In some examples, the statistical drafter analysis circuitry 210 can select a filter based on the identified pattern (e.g., a filter that ignores the pattern of the gridlines, etc.).

At block 850, the geometric analysis circuitry 208 analyzes the geometry and metadata of nearby components to the identified components based on the filter selected by the statistical drafter analysis circuitry 210. The application of the filter to the schematic by the geometric analysis circuitry 208 refines the identification of the components of the schematic by filtering based on the patterns identified during the statistical analysis. In other words, the geometric analysis circuitry 208 can identify building components (e.g., beams, doors, windows, etc.) based on drafter intent identified by comparison to at least one of industry standards and/or patterns in the schematic. Further, the geometric analysis circuitry 208 can further define the nearby schematic components and their geometric relationship to the identified components. In some examples, the geometric analysis circuitry 208 can identify the nearby schematic components as beams, windows, and/or other components, and can define the spatial arrangement and/or geometric relationship (e.g., angular, orientation, etc.) of a first component to a second component (e.g., from a beam to a window, etc.). For example, the geometric analysis circuitry 208 can identify a beam and a window, define the orientation of the beam to the window, and the angle between the beam and the window.

At block 860, the building information model generation circuitry 212 generates a building information model database of components identified from the analyses of the geometric analysis circuitry 208 and the statistical drafter analysis circuitry 210. The building information model generation circuitry 212 includes in the building information model database the identification of components in the schematic, metadata included for components in the schematic, the scale of the schematic, and other data identifiable from the schematic. The building information model database serves as a repository of known components from which annotations, relational databases, and 3-D models can be generated. As the repository of known components continues to increase for the schematic, the accuracy and precision of the actionable outputs increases. The precision of the actionable output increases because there is more information in the building information model database for the generation of the actionable outputs. In particular, the building information model database can have more information relating to sizes of components in a schematic and that can inform the sizes of other components within the same schematic and other schematics. Additionally, the building information model database can store data relating to component codes and metadata for various components and can be used to match to components in a schematic for increased and faster precision in identification of components.

At block 870, the annotation circuitry 214 annotates the schematic based on the identified components. In some examples, the annotation circuitry 214 finds the nearest component to the selected features. Finding the nearest component to the selected features enables accurate tagging (e.g., labelling) of components of the schematic without manual intervention. To find the nearest component, the annotation circuitry 214 identifies a line of a component that is closest to the selected feature. In some examples, identification of the nearest component can include tagging and/or labelling of that component by the annotation circuitry 214 with the selected feature (e.g., attaching a component code to the nearest component, etc.).

In examples where the selected feature is a component code, the annotation circuitry 214 finds the nearest line of a component that is closest (i.e., nearest linear distance and/or proximate) to the component code. In some examples, the nearest line is a beam. The annotation circuitry 214 scans the schematic for lines near the identified features. The lines correspond to components of the schematic that are tagged with the identification of the selected feature nearest to that line.

In accordance with the example of block 820, after identification of components with the certain beam angle, the line nearest to the identified beam angle is associated as a component with that certain beam angle. Additionally, in examples (such as above), where the selected feature is line thickness (e.g., a line that is ⅛″ thick), the annotation circuitry 214 finds the nearest line to the thickness (e.g., the annotation circuitry 214 finds the nearest line and/or identifies a line that is ⅛″ thick).

In some examples, as described above in connection to FIG. 2, a component label process is used to determine the nearest component to an identified feature and tag the component for annotation. Further, in some examples, a label is affixed to the component identified as having a selected feature. The label corresponds to metadata that the annotation circuitry 214 can utilize to annotate the component.

In some examples, the annotation circuitry 214 can also measure the identified nearest component. In some examples, the annotation circuitry 214 measures the nearest line to the selected feature of the nearest component. The annotation circuitry 214 can measure the identified nearest component by picking a point on the nearest line and extending the line in opposite directions a predefined amount, by selecting the endpoints of the component and computing length based on the drawing scale, and/or any other methods of measurement. In some examples, the annotation circuitry 214 determines the predefined amount by finding the x-y coordinates of the ends of the component and calculating the slope between the ends of the component. The annotation circuitry 214 uses the drawing scale to determine the predefined amount based on the calculated slope and distance between the ends of the component.

In some examples, the annotation circuitry 214 annotates the selected features with metadata from the database 222 of FIG. 2 corresponding to the component codes recognized by the object recognition circuitry 206. This metadata can be correlated to beam codes and/or other values that identify the selected features to the output generation circuitry 216. For example, the annotation circuitry 214 can label to identify the selected features as a certain type of material and/or component (e.g., a certain type of beam). After annotation by the annotation circuitry 214, control returns to block 630.

FIG. 9 is a flowchart representative of example machine readable instructions and/or example operations 630 that may be executed, instantiated, and/or performed by programmable circuitry to annotate the schematic. The example machine-readable instructions and/or the example operations 630 of FIG. 9 begin at block 910, at which the output generation circuitry 216 outputs annotations to the schematic. In some examples, the annotations to the schematic are stored in the database 222 so that they can be recalled for later usage.

At block 920, the output generation circuitry 216 determines whether to generate the relational database of the schematic. As described above, the relational database includes a material list (e.g., quantity of materials necessary to complete the schematic, etc.), a list of the types of materials required, components corresponding to a certain dimension (e.g., beams in the horizontal and/or vertical direction, etc.), and/or another configuration of a feature of the annotated schematic. Further, the relational database can store information regarding how areas of a building of a schematic relate in a spatial arrangement to each other (e.g., how a first area relates to a second area, wherein a first area is on a first page and a second area is on a second page of the schematic, etc.). In some examples, a schematic is not able to fit on a single page, and multiple pages are used to view one schematic. In these examples, a first area of the schematic may represent a first building area and be located on a first page of the schematic, and a second area of the schematic may represent a second building area and be located on a second page of the schematic. The relational database stores information regarding how the first area and the second area are related to each other in space (e.g., if the first area is on a higher level, skewed from the second area, etc.) and places the first area in a spatial arrangement in relation to the second area despite the separation in pages. If the output generation circuitry 216 determines to generate the relational database (block 920: YES), the output generation circuitry 216 generates the relational database at block 930. If the relational database is generated, the relational database can be stored in the database 222 and may be recalled for later usage. In some examples, the determination of whether to generate the relational database may be based on whether a button was selected to generate the relational database (e.g., the button 540 of FIG. 5B) and/or whether there is sufficient data in the annotated schematic to enable generation of the relational database. If the output generation circuitry 216 determines not to generate the relational database (block 920: NO), control proceeds to block 940.

At block 940, the output generation circuitry 216 determines whether to generate the 3D model of the schematic. If the output generation circuitry 216 determines to generate the 3D model (block 940: YES), the output generation circuitry 216 generates the 3D model. If the 3D model is generated, the 3D model can be stored in the database 222 and may be recalled for later usage. If the output generation circuitry 216 determines not to generate the 3D model (block 960: NO), control proceeds to block 630. In some examples, the determination not to generate the 3D model can be based on whether a button was selected triggering generation of the 3D model and/or whether there are sufficient data points to enable generation of the 3D model. After determination of generation and/or generation of the actionable output by the output generation circuitry 216, control returns to block 630 and the process ends.

FIG. 10 is a flowchart representative of example machine readable instructions and/or example operations 640 that may be executed, instantiated, and/or performed by programmable circuitry to annotate the schematic. The example machine-readable instructions and/or the example operations 640 of FIG. 10 begin at block 1010, at which the user input determination circuitry 218 determines whether the user has an input to at least one of the annotations to the schematic, the relational database, or the 3D model. The user input determination circuitry 218 can determine the user input via a user interface and/or any other user interfacing device (e.g., a keyboard, etc.). If the user input determination circuitry 218 determines the user has an input to at least one of the annotations to the schematic, the relational database, or the 3D model (block 1010: YES), control proceeds to block 1020. If the user input determination circuitry 218 determines the user does not have an input to at least one of the annotations to the schematic, the relational database, or the 3D model (block 1010: NO), control returns to block 1010 and continues polling until the user has an input. For example, the user input determination circuitry 218 can determine that the user has an input to modify an annotation to at least one of the annotations to the schematic (e.g., the relational database, the 3-D model, etc.).

At block 1020, the user input determination circuitry 218 receives the user input via an interface. Further, at block 1030, the user input determination circuitry 218 displays the user input to the user in real time. In some examples, the user input determination circuitry 218 displays an edit from the user to the annotations to the schematic via the interface to the user. In other examples, the user input determination circuitry 218 can display an edit to either the relational database and/or the 3D model via the interface to the user. In the above example, the user input determination circuitry 218 displays the edit to the annotation to the annotations to the schematic (e.g., the relational database, the 3-D model, etc.) to the user.

At block 1040, the user input determination circuitry 218 determines whether the user confirms the user input. In other words, the user input determination circuitry 218 determines whether the user accepts and/or approves of the changes to the annotations to the schematic, the relational database, and/or the 3D model. If the user input determination circuitry 218 determines the user confirms the user input (block 1040: YES), control proceeds to block 1050. If the user input determination circuitry 218 determines the user confirms the user input (block 1040: NO), control returns to block 1020 to receive another user input via the user interface. Following the above example, the user input determination circuitry 218 receives confirmation from the user of the user input. In this example, confirmation can be received via a button on a user interface, voice confirmation, biometric confirmation, keyboard confirmation, and/or other input confirmation.

At block 1050, the user input determination circuitry 218 adds the confirmed user input to the actionable output (e.g., the annotations to the schematic, the relational database, and/or the 3D model). In some examples, the confirmed user input may be one edit and/or multiple edits. After the user is finished with edits, control returns to block 640 and the process ends. In the above example, the user input is integrated with the annotations to the schematic (e.g., the relational database, the 3-D model, etc.) so that future viewing and/or downloads of the annotations to the schematic (e.g., the relational database, the 3-D model, etc.) will include the user edit.

FIG. 11 is a block diagram of an example programmable circuitry platform 1100 structured to execute and/or instantiate the example machine-readable instructions and/or the example operations of FIGS. 6-10 to implement the schematic transformation circuitry of FIG. 2. The programmable circuitry platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1100 of the illustrated example includes programmable circuitry 1112. The programmable circuitry 1112 of the illustrated example is hardware. For example, the programmable circuitry 1112 can be implemented by one or more integrated circuits, logic circuits, FPGAs, microprocessors, CPUs, GPUs, DSPs, and/or microcontrollers from any desired family or manufacturer. The programmable circuitry 1112 may be implemented by one or more semiconductor based (e.g., silicon based) devices. In this example, the programmable circuitry 1112 implements the filter circuitry 202, the scale determination circuitry 204, the object recognition circuitry 206, the object recognition circuitry 206, the geometric analysis circuitry 208, the statistical drafter analysis circuitry 210, the building information model generation circuitry 212, the annotation circuitry 214, the output generation circuitry 216, and the user input determination circuitry 218.

The programmable circuitry 1112 of the illustrated example includes a local memory 1113 (e.g., a cache, registers, etc.). The programmable circuitry 1112 of the illustrated example is in communication with main memory 1114, 1116, which includes a volatile memory 1114 and a non-volatile memory 1116, by a bus 1118. The volatile memory 1114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1116 may be implemented by flash memory and/or any other desired type of memory device. Access to the main memory 1114, 1116 of the illustrated example is controlled by a memory controller 1117. In some examples, the memory controller 1117 may be implemented by one or more integrated circuits, logic circuits, microcontrollers from any desired family or manufacturer, or any other type of circuitry to manage the flow of data going to and from the main memory 1114, 1116.

The programmable circuitry platform 1100 of the illustrated example also includes interface circuitry 1120. The interface circuitry 1120 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1122 are connected to the interface circuitry 1120. The input device(s) 1122 permit(s) a user (e.g., a human user, a machine user, etc.) to enter data and/or commands into the programmable circuitry 1112. The input device(s) 1122 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1124 are also connected to the interface circuitry 1120 of the illustrated example. The output device(s) 1124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1120 of the illustrated example, thus, typically includes a graphics driver card, a graphics driver chip, and/or graphics processor circuitry such as a GPU.

The interface circuitry 1120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1100 of the illustrated example also includes one or more mass storage discs or devices 1128 to store firmware, software, and/or data. Examples of such mass storage discs or devices 1128 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1132, which may be implemented by the machine readable instructions of FIGS. 6-10, may be stored in the mass storage device 1128, in the volatile memory 1114, in the non-volatile memory 1116, and/or on at least one non-transitory computer readable storage medium such as a CD or DVD which may be removable.

FIG. 12 is a block diagram of an example implementation of the programmable circuitry 1112 of FIG. 11. In this example, the programmable circuitry 1112 of FIG. 11 is implemented by a microprocessor 1200. For example, the microprocessor 1200 may be a general-purpose microprocessor (e.g., general-purpose microprocessor circuitry). The microprocessor 1200 executes some or all of the machine-readable instructions of the flowcharts of FIGS. 6-10 to effectively instantiate the circuitry of FIG. 2 as logic circuits to perform operations corresponding to those machine readable instructions. In some such examples, the circuitry of FIG. 2 is instantiated by the hardware circuits of the microprocessor 1200 in combination with the machine-readable instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine readable instructions and/or operations represented by the flowcharts of FIGS. 6-10.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Additionally or alternatively, the first bus 1204 may be implemented by any other type of computing or electrical bus. The cores 1202 may obtain data, instructions, and/or signals from one or more external devices by example interface circuitry 1206. The cores 1202 may output data, instructions, and/or signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and/or instructions. Data and/or instructions may be transferred (e.g., shared) by writing to and/or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic and/or logic operations on the data within the corresponding core 1202. The AL circuitry 1216 of some examples performs integer based operations. In other examples, the AL circuitry 1216 also performs floating-point operations. In yet other examples, the AL circuitry 1216 may include first AL circuitry that performs integer-based operations and second AL circuitry that performs floating-point operations. In some examples, the AL circuitry 1216 may be referred to as an Arithmetic Logic Unit (ALU).

The registers 1218 are semiconductor-based structures to store data and/or instructions such as results of one or more of the operations performed by the AL circuitry 1216 of the corresponding core 1202. For example, the registers 1218 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure, such as by being distributed throughout the core 1202 to shorten access time. The second bus 1222 may be implemented by at least one of an I2C bus, a SPI bus, a PCI bus, or a PCIe bus.

Each core 1202 and/or, more generally, the microprocessor 1200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1200 is a semiconductor device fabricated to include many transistors interconnected to implement the structures described above in one or more integrated circuits (ICs) contained in one or more packages.

The microprocessor 1200 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1200, in the same chip package as the microprocessor 1200 and/or in one or more separate packages from the microprocessor 1200.

FIG. 13 is a block diagram of another example implementation of the programmable circuitry 1112 of FIG. 11. In this example, the programmable circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine readable instructions. However, once configured, the FPGA circuitry 1300 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1200 of FIG. 12 described above (which is a general purpose device that may be programmed to execute some or all of the machine readable instructions represented by the flowchart(s) of FIGS. 6-10 but whose interconnections and logic circuitry are fixed once fabricated), the FPGA circuitry 1300 of the example of FIG. 13 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 6-10. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 6-10. As such, the FPGA circuitry 1300 may be configured and/or structured to effectively instantiate some or all of the operations/functions corresponding to the machine readable instructions of the flowchart(s) of FIGS. 6-10 as dedicated logic circuits to perform the operations/functions corresponding to those software instructions in a dedicated manner analogous to an ASIC. Therefore, the FPGA circuitry 1300 may perform the operations/functions corresponding to the some or all of the machine readable instructions of FIGS. 6-10 faster than the general-purpose microprocessor can execute the same.

In the example of FIG. 13, the FPGA circuitry 1300 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1300 of FIG. 13 may access and/or load the binary file to cause the FPGA circuitry 1300 of FIG. 13 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1300 of FIG. 13 to cause configuration and/or structuring of the FPGA circuitry 1300 of FIG. 13, or portion(s) thereof.

The FPGA circuitry 1300 of FIG. 13, includes example input/output (I/O) circuitry 1302 to obtain and/or output data to/from example configuration circuitry 1304 and/or external hardware 1306. For example, the configuration circuitry 1304 may be implemented by interface circuitry that may obtain a binary file, which may be implemented by a bit stream, data, and/or machine-readable instructions, to configure the FPGA circuitry 1300, or portion(s) thereof. In some such examples, the configuration circuitry 1304 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1306 may be implemented by external hardware circuitry. For example, the external hardware 1306 may be implemented by the microprocessor 1200 of FIG. 12.

The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations/functions that may correspond to at least some of the machine readable instructions of FIGS. 6-10 and/or other desired operations. The logic gate circuitry 1308 shown in FIG. 13 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of the electrical structures and/or the logic gates to form circuits to perform desired operations/functions. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example dedicated operations circuitry 1314. In this example, the dedicated operations circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 and/or an example DSP 1322. Other general purpose programmable circuitry 1318 may additionally or alternatively be present such as a GPU, an XPU, etc., that can be programmed to perform other operations.

Although FIGS. 11 and 12 illustrate two example implementations of the programmable circuitry 1112 of FIG. 11, many other approaches are contemplated. For example, FPGA circuitry may include an on-board CPU, such as one or more of the example CPU 1320 of FIG. 13. Therefore, the programmable circuitry 1112 of FIG. 11 may additionally be implemented by combining at least the example microprocessor 1200 of FIG. 12 and the example FPGA circuitry 1300 of FIG. 13. In some such hybrid examples, one or more cores 1202 of FIG. 12 may execute a first portion of the machine readable instructions represented by the flowchart(s) of FIGS. 6-10 to perform first operation(s)/function(s), the FPGA circuitry 1300 of FIG. 13 may be configured and/or structured to perform second operation(s)/function(s) corresponding to a second portion of the machine readable instructions represented by the flowcharts of FIG. 6-10, and/or an ASIC may be configured and/or structured to perform third operation(s)/function(s) corresponding to a third portion of the machine readable instructions represented by the flowcharts of FIGS. 6-10.

It should be understood that some or all of the circuitry of FIG. 2 may, thus, be instantiated at the same or different times. For example, same and/or different portion(s) of the microprocessor 1200 of FIG. 12 may be programmed to execute portion(s) of machine-readable instructions at the same and/or different times. In some examples, same and/or different portion(s) of the FPGA circuitry 1300 of FIG. 13 may be configured and/or structured to perform operations/functions corresponding to portion(s) of machine-readable instructions at the same and/or different times.

In some examples, some or all of the circuitry of FIG. 2 may be instantiated, for example, in one or more threads executing concurrently and/or in series. For example, the microprocessor 1200 of FIG. 12 may execute machine readable instructions in one or more threads executing concurrently and/or in series. In some examples, the FPGA circuitry 1300 of FIG. 13 may be configured and/or structured to carry out operations/functions concurrently and/or in series. Moreover, in some examples, some or all of the circuitry of FIG. 2 may be implemented within one or more virtual machines and/or containers executing on the microprocessor 1200 of FIG. 12.

In some examples, the programmable circuitry 1112 of FIG. 11 may be in one or more packages. For example, the microprocessor 1200 of FIG. 12 and/or the FPGA circuitry 1300 of FIG. 13 may be in one or more packages. In some examples, an XPU may be implemented by the programmable circuitry 1112 of FIG. 11, which may be in one or more packages. For example, the XPU may include a CPU (e.g., the microprocessor 1200 of FIG. 12, the CPU 1320 of FIG. 13, etc.) in one package, a DSP (e.g., the DSP 1322 of FIG. 13) in another package, a GPU in yet another package, and an FPGA (e.g., the FPGA circuitry 1300 of FIG. 13) in still yet another package.

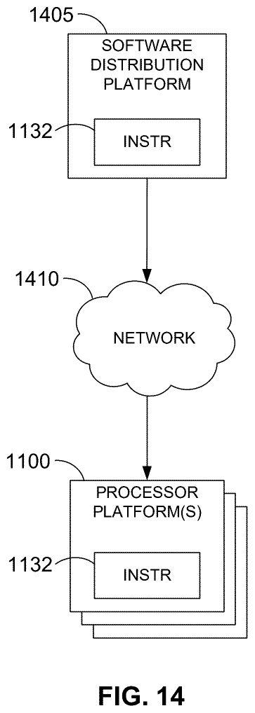

A block diagram illustrating an example software distribution platform 1405 to distribute software such as the example machine readable instructions 1132 of FIG. 11 to other hardware devices (e.g., hardware devices owned and/or operated by third parties from the owner and/or operator of the software distribution platform) is illustrated in FIG. 14. The example software distribution platform 1405 may be implemented by any computer server, data facility, cloud service, etc., capable of storing and transmitting software to other computing devices. The third parties may be customers of the entity owning and/or operating the software distribution platform 1405. For example, the entity that owns and/or operates the software distribution platform 1405 may be a developer, a seller, and/or a licensor of software such as the example machine readable instructions 1132 of FIG. 11. The third parties may be consumers, users, retailers, OEMs, etc., who purchase and/or license the software for use and/or re-sale and/or sub-licensing. In the illustrated example, the software distribution platform 1405 includes one or more servers and one or more storage devices. The storage devices store the machine readable instructions 1132, which may correspond to the example machine readable instructions of FIGS. 6-10, as described above. The one or more servers of the example software distribution platform 1405 are in communication with an example network 1410, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1132 from the software distribution platform 1405. For example, the software, which may correspond to the example machine readable instructions of FIG. 6-10, may be downloaded to the example programmable circuitry platform 1100, which is to execute the machine readable instructions 1132 to implement the schematic transformation circuitry. In some examples, one or more servers of the software distribution platform 1405 periodically offer, transmit, and/or force updates to the software (e.g., the example machine readable instructions 1132 of FIG. 11) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that generate an actionable output for a schematic. Disclosed systems, apparatus, articles of manufacture, and methods improve the efficiency of using a computing device by generating an actionable output for a schematic wherein the actionable output includes at least one of an annotated schematic, a relational database, and a 3D model. Disclosed systems, apparatus, articles of manufacture, and methods are accordingly directed to one or more improvement(s) in the operation of a machine such as a computer or other electronic and/or mechanical device. The actionable output of the schematic improves the efficiency of the computing device as it corrects errors of components identified in schematics through comparison to references. These errors are imperceptible to the human eye as they are within the manner of several pixels (e.g., 30 pixels, 10 pixels, etc.). Humans are unable to perceive whether a component on a schematic is over or under extended by several pixels without the aid of technology. Accordingly, the actionable output of the schematic improves the efficiency of a computing device by identifying these errors and generating the updated schematic before human usage. Otherwise, humans would have to attempt to build the structure in the schematic, re-run the schematic, attempt to identify the error using the computer resources endlessly, and waste computer resources to attempt to identify an imperceptible error. Therefore, prior to human usage and implementation in the three-dimensional world, the actionable output is compared to industry norms and/or references in a way that enables detailed, efficient, and real-time detection of errors for remediation before implementation of the schematic in the real world. Accordingly, the actionable output of the schematic can be updated to reflect corrections to the identified errors to ensure safety and proactively prevent a construction accident.

Example methods, apparatus, systems, and articles of manufacture to generate an actionable output for a schematic are disclosed herein. Further examples and combinations thereof include the following:

Example 1 includes a method comprising preprocessing a schematic, analyzing the schematic, an analysis based on a feature of a component of the schematic, generating an actionable output from the schematic, the actionable output including at least one of an annotated schematic, a relational database, or a three-dimensional model, identifying an error based on a comparison of the identified component and a reference, adjusting the identified component based on the error to generate a corrected identified component, and generating an updated schematic in response to adjusting the identified component including the corrected identified component, wherein the corrected identified component corrects the error and replaces the identified component.

Example 2 includes the method of example 1, wherein the identified component is a beam, the error is a beam length, the reference is a predicted end of a beam, and adjusting the identified component based on the error to generate the corrected identified component includes: based on a determination that the beam is less than the predicted end of a beam, extend the beam in the updated schematic; and based on a determination that the beam is greater than the predicted end of the beam, retract the beam in the updated schematic.

Example 3 includes the method of example 1, wherein preprocessing the schematic further includes filtering the schematic, wherein the filtered schematic includes the component for annotation.

Example 4 includes the method of example 1, wherein analyzing the schematic further includes attaching a label to the component, wherein the label corresponds to the feature of the analysis.

Example 5 includes the method of example 4, wherein the label further includes metadata to identify the component.

Example 6 includes the method of example 1, wherein analyzing the schematic further includes extracting a component code from the component of the schematic, matching the component codes to a database, the database including metadata to identify the component, and annotating the schematic with the metadata of the database.

Example 7 includes the method of example 1, wherein the relational database of the schematic includes at least one of a list of materials of components in the schematic, identification of a type of component in the schematic, and a dimension of a component in the schematic.

Example 8 includes an apparatus comprising interface circuitry, machine-readable instructions, and at least one processor circuit to be programmed by the machine-readable instructions to preprocess a schematic, analyze the schematic, an analysis based on a feature of a component of the schematic, and generate an actionable output for the schematic, the actionable output includes at least one of an annotated schematic, a relational database, and a three-dimensional model.

Example 9 includes the apparatus of example 8, wherein one or more of the at least one processor circuit is to analyze the schematic by determining a drawing scale of the schematic.

Example 10 includes the apparatus of example 8, wherein one or more of the at least one processor circuit is to preprocess the schematic by filtering the schematic, wherein the filtered schematic includes the component for annotation.

Example 11 includes the apparatus of example 8, wherein one or more of the at least one processor circuit is to analyze the schematic by attaching a label to a component, wherein the label corresponds to the feature of the analysis.

Example 12 includes the apparatus of example 11, wherein the label further includes metadata to identify the component.

Example 13 includes the apparatus of example 8, wherein one or more of the at least one processor circuit is to analyze the schematic by extracting a component code from the component of the schematic, matching the component codes to a database, the database including metadata to identify the component, and annotating the schematic with the metadata of the database.

Example 14 includes the apparatus of example 8, wherein the relational database of the schematic includes at least one of a list of materials of components in the schematic, identification of a type of component in the schematic, and a dimension of a component in the schematic.

Example 15 includes At least one non-transitory computer-readable medium comprising machine-readable instructions to cause at least one processor circuit to preprocess a schematic, analyze the schematic, an analysis based on a feature of a component of the schematic, and generate an actionable output from the schematic, the actionable output including at least one of an annotated schematic, a relational database, or a three-dimensional model.

Example 16 includes the non-transitory computer-readable medium of example 15, wherein machine-readable instructions are to cause one or more of the at least one processor circuit to analyze the schematic by determining a drawing scale of the schematic.

Example 17 includes the non-transitory computer-readable medium of example 15, wherein the machine-readable instructions are to cause one or more of the at least one processor circuit to preprocess the schematic by filtering the schematic, wherein the filtered schematic includes the component for annotation.

Example 18 includes the non-transitory computer-readable medium of example 15, wherein the machine-readable instructions are to cause one or more of the at least one processor circuit to analyze the schematic by attaching a label to a component, wherein the label corresponds to the feature of the analysis.

Example 19 includes the non-transitory computer-readable medium of example 18, wherein the label further includes metadata to identify the component.

Example 20 includes the non-transitory computer-readable medium of example 15, wherein the machine-readable instructions are to cause one or more of the at least one processor circuit is to analyze the schematic by extracting a component code from the component of the schematic, matching the component codes to a database, the database including metadata to identify the component, and annotating the schematic with the metadata of the database.

Example 21 includes the non-transitory computer-readable medium of example 15, wherein the relational database of the schematic includes at least one of a list of materials of components in the schematic, identification of a type of component in the schematic, and a dimension of a component in the schematic.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A method comprising:
identifying a component of a schematic, wherein the identification of the component of the schematic is based on an analysis of selected features of the schematic;
generating a database including the identified component of the schematic;
generating an actionable output from the schematic based on the identified component of the database, the actionable output including at least one of annotations to the schematic, a relational database, or a three-dimensional model;
identifying an error based on a comparison of the identified component and a reference;
adjusting the identified component based on the error to generate a corrected identified component; and
generating an update to replace the schematic in response to adjusting the identified component including the corrected identified component, wherein the corrected identified component corrects the error and replaces the identified component.

2. The method of claim 1, wherein the identified component is a beam, the error is a beam length, the reference is a predicted end of the beam, and adjusting the identified component based on the error to generate the corrected identified component includes:
based on a determination that the beam is less than the predicted end of the beam, extend the beam in the schematic; and
based on a determination that the beam is greater than the predicted end of the beam, retract the beam in the schematic.

3. The method of claim 1, wherein identifying the component of the schematic further includes performing a geometric analysis of the selected features and the component of the schematic, wherein the geometric analysis includes a determination of an intent of a drafter based on a comparison of the schematic to an industry standard.

4. The method of claim 3, wherein the geometric analysis further includes a determination of a geometric relationship between the selected features and the component of the schematic.

5. The method of claim 1, wherein identifying the component of the schematic further includes performing a statistical analysis, wherein the statistical analysis determines a pattern in the schematic based on an intent of a drafter.

6. The method of claim 5, further including:
selecting a filter based on the pattern identified by the statistical analysis; and
performing another geometric analysis using the filter to identify the component of the schematic.

7. The method of claim 1, further including, in response to generating the database including the identified component of the schematic, annotating the schematic based on the identified components.

8. An apparatus comprising:
interface circuitry;
machine-readable instructions; and
at least one processor circuit to be programmed by the machine-readable instructions to:
identify a component of a schematic, wherein the identification of the component of the schematic is based on an analysis of selected features of the schematic;
generate a database including the identified component of the schematic; and
generate an actionable output from the schematic based on the identified component of the database, the actionable output including at least one of annotations to the schematic, a relational database, or a three-dimensional model.

9. The apparatus of claim 8, wherein to identify the component of the schematic one or more of the at least one processor circuit is to filter the schematic based on the selected features.

10. The apparatus of claim 8, wherein to identify the component of the schematic one or more of the at least one processor circuit is to perform a geometric analysis of the selected features and the component of the schematic, wherein the geometric analysis includes a determination of an intent of a drafter based on a comparison of the schematic to an industry standard.

11. The apparatus of claim 10, wherein the geometric analysis further includes a determination of a geometric relationship between the selected features and the component of the schematic.

12. The apparatus of claim 8, wherein identifying the component of the schematic further includes performing a statistical analysis, wherein the statistical analysis determines a pattern in the schematic based on an intent of a drafter.

13. The apparatus of claim 12, wherein one or more of the at least one processor circuit is to:
select a filter based on the pattern identified by the statistical analysis; and
perform another geometric analysis using the filter to identify the component of the schematic.

14. The apparatus of claim 8, wherein, in response to generating the database including the identified component of the schematic, one or more of the at least one processor circuit is to annotate the schematic based on the identified components.

15. At least one non-transitory computer-readable medium comprising machine-readable instructions to cause at least one processor circuit to:
identify a component of a schematic, wherein the identification of the component of the schematic is based on an analysis of selected features of the schematic;
generate a database including the identified component of the schematic; and
generate an actionable output from the schematic based on the identified component of the database, the actionable output including at least one of annotations to the schematic, a relational database, or a three-dimensional model.

16. The non-transitory computer-readable medium of claim 15, wherein the machine-readable instructions are to cause one or more of the at least one processor circuit to filter the schematic based on the selected features.

17. The non-transitory computer-readable medium of claim 15, wherein the machine-readable instructions are to cause one or more of the at least one processor circuit to identify the component of the schematic one or more of the at least one processor circuit is to perform a geometric analysis of the selected features and the component of the schematic, wherein the geometric analysis includes a determination of an intent of a drafter based on a comparison of the schematic to an industry standard.

18. The non-transitory computer-readable medium of claim 17, wherein the geometric analysis further includes a determination of a geometric relationship between the selected features and the component of the schematic.

19. The non-transitory computer-readable medium of claim 15, wherein identifying the component of the schematic further includes performing a statistical analysis, wherein the statistical analysis determines a pattern in the schematic based on an intent of a drafter.

20. The non-transitory computer-readable medium of claim 19, wherein the machine-readable instructions are to cause one or more of the at least one processor circuit is to:
select a filter based on the pattern identified by the statistical analysis; and
perform another geometric analysis using the filter to identify the component of the schematic.
